(19) United States
(12) Patent Application Publication
(10) Pub. No.: US 2006/0214715 A1
(43) Pub. Date: Sep. 28, 2006

(54) Delay circuit and electronic circuit including delay circuit

(75) Inventor: Hajime Takashima, Anpachi-gun (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SANYO ELECTRIC CO., LTD., Moriguchi-shi (JP)

(21) Appl. No.: 11/389,133

(22) Filed: Mar. 27, 2006

(30) Foreign Application Priority Data
Mar. 28, 2005 (JP) 2005-090739

(51) Int. Cl. H03H 11/26

(52) U.S. Cl. 327/261

(57) ABSTRACT

The objective is to provide a delay circuit and an electronic circuit including a delay circuit which are capable of changing the operation speed of a circuit system including an operational amplifier and the delay circuit with ease. An electronic circuit includes a voltage generation circuit which generates a bias voltage, an operational amplifier which operates with a constant voltage and receives the bias voltage from the voltage generation circuit, and a delay circuit which operates with the constant voltage and receives the bias voltage from the voltage generation circuit so as to reduce fluctuations of current flowing in the delay circuit by the bias voltage.

### BACKGROUND OF THE INVENTION

1. Field of the Invention

This invention relates to a delay circuit and an electronic circuit including the delay circuit, which are designed to restrain variations in delay values.

2. Description of the Related Art

Delay circuits are used extensively in digital circuits such as in a clock generation circuit and the like. The delay circuits are liable to have variations in delay values due to piece-to-piece variations of devices included in the delay circuits, temperature changes when used, and voltage fluctuations by a power supply. In order to restrain the variations in delay values, there is a means for using a bias voltage generated by the other voltage source set apart from the power supply as a bias voltage for inverters that constitute the delay circuit. This means is disclosed, for example, in Japanese Published Unexamined Patent Application No. Hei 10-303711.

Operational amplifiers are used generally in a sample-and-hold circuit, an amplifier circuit, and a comparator, all of which are included in an analog to digital converter and the like. In order for the operational amplifier to operate with high accuracy, it is necessary not only to supply differential amplifier circuits in the operational amplifier with a power supply voltage, but also to supply a bias circuit in the operational amplifier with a bias voltage.

Additionally, circuits such as a sample-and-hold circuit in pipelined analog to digital converters and the like require an external clock to alter input and output timing of signals. In the case where the foregoing circuits need a clock signal whose period is different from the period of a system clock, a new clock signal is required to be generated by using a delay circuit and the like. Thus, in order for the sample-and-hold circuit and an amplifier circuit including operational amplifiers to operate with high accuracy, it is necessary to configure a circuit comprising a bias voltage generation circuit and the delay circuit.

However, in the aforementioned circuit configuration, the operational amplifier and the delay circuit must be redesigned individually when changing the operation speed of the entire circuit.

### SUMMARY OF THE INVENTION

It is an object of the present invention to provide a delay circuit and an electronic circuit including a delay circuit which are capable of changing the operation speed of the circuit system including an operational amplifier and the delay circuit with ease.

An electronic circuit according to an aspect of the present invention comprises a voltage generation circuit which generates a bias voltage, an operational amplifier which operates with a constant voltage and receives the bias voltage from the voltage generation circuit, and a delay circuit which operates with the constant voltage and receives the bias voltage from the voltage generation circuit so as to reduce fluctuations of current flowing in the delay circuit by the bias voltage. The “constant voltage” in the present invention may be a power supply voltage.

According to this aspect of the present invention, since the bias voltage for the operational amplifier and the bias voltage for the delay circuit are controlled concurrently, changing the operation speed of the entire electronic circuit can be achieved with ease.

An electronic circuit according to another aspect of the present invention comprises a voltage generation circuit which generates an bias voltage, an operational amplifier which operates with a constant voltage and receives the bias voltage from the voltage generation circuit, a delay circuit which operates with the constant voltage and receives the bias voltage from the voltage generation circuit so as to reduce fluctuations of current flowing in the delay circuit by the bias voltage, and a clock generation circuit which generates a clock signal to supply the operational amplifier and an additional circuit added to the operational amplifier. The clock signal is generated based on a signal before being delayed by the delay circuit and on a signal after being delayed by the delay circuit. The “additional circuit” in the present invention may be a switch connected at least to one of an input terminal and an output terminal of the operational amplifier.

According to this aspect of the present invention, since the bias voltage for the operational amplifier and the bias voltage for the delay circuit are controlled concurrently, changing the operation speed of the entire electronic circuit can be achieved with ease.

Further, a regulator circuit may be connected to each of the voltage generation circuit and the delay circuit. The “regulator circuit” in the present invention may be one of a step-up transformer and a step-down transformer. According to this aspect, even in the case that a bias voltage required for the operational amplifier is different from a bias voltage required for the delay circuit, a voltage generation circuit can be shared with ease by the operational amplifier and the delay circuit.

The voltage generation circuit may fluctuate a voltage to be supplied to the delay circuit in accordance with fluctuations of the constant voltage. According to this aspect, even if the constant voltage to be employed as a voltage source for the delay circuit fluctuates, restraining fluctuations of current flowing in the delay circuit makes it possible to restrain the variations in delay values since the bias voltage varies in accordance with the fluctuations of the constant voltage.

A delay circuit according to an additional aspect of the present invention operates with a constant voltage and receives a bias voltage so as to reduce fluctuations of current flowing in the delay circuit, wherein the bias voltage is supplied by a voltage source provided to supply the bias voltage to an operational amplifier disposed outside of the delay circuit.

According to this aspect, the bias voltage for the operational amplifier and the bias voltage for the delay circuit can be controlled concurrently. Hence, the delay circuit which varies its delay values in conjunction with the operation speed of the operational amplifier can be achieved.

It is noted that any combinations and arrangements of the aforementioned constituents and any modifications on methods, devices, and systems of the present invention, may be resorted to as aspects of the present invention.

### BRIEF DESCRIPTION OF THE DRAWINGS

FIG. 1 is a block diagram showing a structure of an electronic circuit according to a first embodiment of the present invention;
FIG. 2A and FIG. 2B are each a timing chart showing clock waveforms of a master clock signal MasterCLK and a delayed clock signal DelayCLK where a delay is added to the MasterCLK by the delay circuit 10, respectively before and after changing the operation speed of the master clock according to the first embodiment of the present invention;

FIG. 3 is a circuit diagram showing the structure of the constant-voltage generation circuit according to the first embodiment of the present invention;

FIG. 4 is a block diagram showing a structure of an electronic circuit according to a modification of the first embodiment of the present invention;

### DETAILED DESCRIPTION OF THE PREFERRED EMBODIMENTS

First of all, knowledge premised in understanding the present invention is now described. A circuit configuration in preferred embodiments of the present invention comprises an operational amplifier and a delay circuit. Operation speed of the operational amplifier and delay values generated by the delay circuit are basically determined by current permeating in each circuit. An increase in current flowing in each circuit leads to an increase in the operation speed of the operational amplifier, and to a decrease in delay values in the delay circuit. The preferred embodiments of the present invention will be hereinafter described in detail based on the premised knowledge described hereinbefore.

FIG. 1 is a block diagram showing a structure of an electronic circuit 100 according to a first embodiment of the present invention. The electronic circuit 100 includes a delay circuit 10, a clock generation circuit 20, a constant voltage generation circuit 30, and a circuit 40 including an operational amplifier 42. The circuit 40 can be any circuits carrying out some functions utilizing the operational amplifier 42, such as an inverting amplifier, a noninverting amplifier, a differentiating circuit, an integrating circuit, an adding circuit, a subtracting circuit, a voltage follower circuit, various filters, an oscillating circuit, a comparator, a peak-value detecting circuit, and a sample-and-hold circuit.

The delay circuit 10 receives a master clock signal generated by a system clock (not shown), provides a delay to the master clock signal, and outputs the delayed clock signal to the clock generation circuit 20. The delay circuit 10 operates with a power supply voltage and a constant voltage generated by the constant voltage generation circuit 30. Delay circuits typically have a configuration of having inverters at the output stage of the delay circuits as shown in FIG. 1 through FIG. 4 in the aforementioned patent application, Japanese Published Unexamined Patent Application No. Hei 10-303711. The switching speed of the inverters varies in response to the amount of current flowing in the inverters. When the current flowing in the inverters is controlled by resistors, the current flowing in the resistors is liable to be fluctuated due to environmental changes such as temperature changes, which cause variations in delay values in the delay circuits.

The delay circuit 10 according to the first embodiment generates a bias voltage to be applied to gates of transistors which constitute the inverters, based on a constant voltage generated by the constant voltage generation circuit 30. The constant voltage may be used as a constant current source. Hence, the restraint of variations in delay values caused by environmental changes and the like can be achieved. Additionally, the restraint of variations in delay values caused by fluctuations of the power supply voltage can be achieved, as described later.

The clock generation circuit 20 generates a clock signal to be supplied to the circuit 40 using a master clock signal MasterCLK output from a system clock and a delayed clock signal output from the delay circuit 10. The clock generation circuit 20 can be composed of a divider, a multiplier, an adder, circuit elements such as a mixer, and any combinations of these. PLL (Phase Locked Loop) may also be included. The clock generation circuit 20 supplies the circuit 40 with the clock signal generated by the clock generation circuit 20.

The constant voltage generation circuit 30 generates a constant voltage and supplies the constant voltage to the operational amplifier 42 included in the circuit 40 and to the delay circuit 10. The operational amplifier 42 includes differential amplifier circuits fabricated by the CMOS (Complementary Metal Oxide Semiconductor) process and the like. The constant voltage generated by the constant voltage generation circuit 30 can be utilized as a bias voltage for the differential amplifier circuits. The differential amplifier circuit also varies the operation speed of the differential amplifier circuit in accordance with the amount of current flowing in the differential amplifier circuit as well as the inverters. The constant voltage generation circuit 30 can supply a reference voltage to the input terminal of the operational amplifier 42. For instance, when a comparator is formed with the operational amplifier 42, an input signal and the reference voltage signal to be compared with the input signal can be supplied to the comparator. Further, when an amplifier is formed with the operational amplifier 42, a reference voltage may be input to the input terminal of the amplifier when an input signal is not being input to the amplifier. Hence, reducing a settling time of an output voltage from the amplifier can be achieved.

A voltage generation circuit originally disposed for supplying a bias voltage to a bias circuit included in the operational amplifier 42 can be employed as the constant voltage generation circuit 30. Further, the constant voltage generation circuit 30 can be connected to the delay circuit 10 by adding a path P2. A detailed configuration of the constant voltage generation circuit 30 will be described later.

The circuit 40 includes the operational amplifier 42 as discussed previously. The operational amplifier 42 has basic functions to amplify an input voltage signal with a gain and output the amplified input voltage signal. The operational amplifier 42 can constitute various circuits such as a comparator and a sample-and-hold circuit and the like by adding resistors, capacitors, and feedback paths as also discussed hereinbefore.

For example, when a switched-capacitor-type sample-and-hold circuit is employed as the circuit 40, switches are set up on an input path of an operational amplifier and on a feedback path which constitute the sample-and-hold circuit. The switches are controlled by the clock signal generated by the clock generation circuit 20. That is to say, by controlling on-off of switches disposed on the input path of the operational amplifier, controlling the timing of sampling an input signal with capacitors connected at an input terminal of the operational amplifier can be achieved. Further, by controlling on-off of all switches, switching between a hold time and an auto-zero time of the sample-and-hold circuit can be adjusted.

On the other hand, in a comparator, by connecting switches to the input and output terminals of the comparator, switching between a comparison time and an auto-zero time of the comparator can be adjusted. Additionally, when capacitors are connected to the input terminal of the comparator with the input being chopper-type, controlling the timing of sampling the input signal by the switch to which the capacitor is connected can be achieved.

In the circuit configuration according to the FIG. 1, the operational amplifier 42 included in the circuit 40 and the delay circuit 10 are controlled concurrently by the output voltage from the constant voltage generation circuit 30. Therefore, by changing the output voltage from the constant voltage generation circuit 30, a current flowing in the operational circuit 42 and a current flowing in the delay circuit 10 can be adjusted simultaneously.

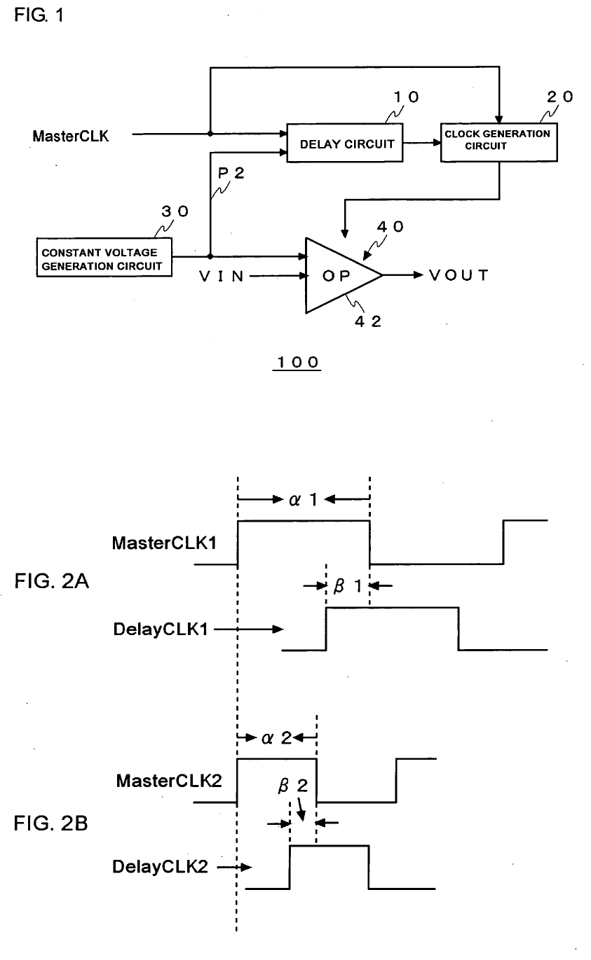

FIG. 2A and FIG. 2B are each a timing chart showing clock waveforms of a master clock signal MasterCLK and a delayed clock signal DelayCLK where a delay is added to the MasterCLK by the delay circuit 10, respectively before and after changing the operation speed of the master clock according to the first embodiment of the present invention. FIG. 2A shows a clock waveform of a master clock signal MasterCLK1 and a clock waveform of a delayed clock signal (DelayCLK1) before changing the operation speed of the master clock. As shown in FIG. 2A, “α1” denotes a half cycle of the MasterCLK1 and “β1” denotes a period obtained by subtracting a delay period from the half cycle α1. FIG. 2B shows a clock waveform of a master clock signal (MasterCLK2) and a clock waveform of a delayed clock signal (DelayCLK2) after changing the operation speed of the master clock. As shown in FIG. 2B, “α2” denotes a half cycle of the MasterCLK2 and “β2” denotes a period obtained by subtracting a delay period from the half cycle α2.

A ratio of α1 to β1, before changing the operation speed of the master clock, is maintained even after changing the speed of the master clock. FIG. 2B shows a case that the speed of the master clock is increased, and the half cycle of MasterCLK2, α2, becomes shorter than α1, the half cycle of MasterCLK1. When the speed of the master clock is increased, the operation speed of the operational amplifier 42 also needs to be increased.

As described previously, by adjusting the bias voltage supplied by the constant voltage generation circuit 30 to increase current flowing in the operational amplifier 42, the operation speed of the operational amplifier 42 can be increased. In the electronic circuit 100, since the constant voltage generation circuit 30 supplies a voltage to the delay circuit 10 as well, the bias voltage of the delay circuit 10 is also adjusted. Current flowing in the delay circuit 10 is increased because of the alterations of the bias voltage. Then, an increase in the switching speed of the inverters included in the delay circuit 10 leads to a decrease in delay time in the delay circuit 10. That is to say, when α1, the half cycle of MasterCLK1 is shortened to α2, the delay period subtracting from α2 is also shortened at the same time. Therefore, a ratio of α, the half cycle of MasterCLK, to β, a period obtained by subtracting a delay period from a is maintained before and after changing the speed of MasterCLK.

Since the ratio of MasterCLK to DelayCLK is maintained before and after changing the speed of MasterCLK, the clock generation circuit 20 can change the speed of a clock signal supplied to the operational amplifier 42 automatically in accordance with changing the operation speed of the operational amplifier 42. Fine adjustment of the current flowing in the operational amplifier 42 and the current flowing in the delay circuit 10 can be achieved by providing a step-up/down transformer and the like on the path between the constant voltage generation circuit 30 and the operational amplifier 42, and on the path between the constant voltage generation circuit 30 and the delay circuit 10. It can also be achieved by changing the driving capacity of transistors to be supplied with the bias voltage in the operational amplifier 42 and the delay circuit 10.

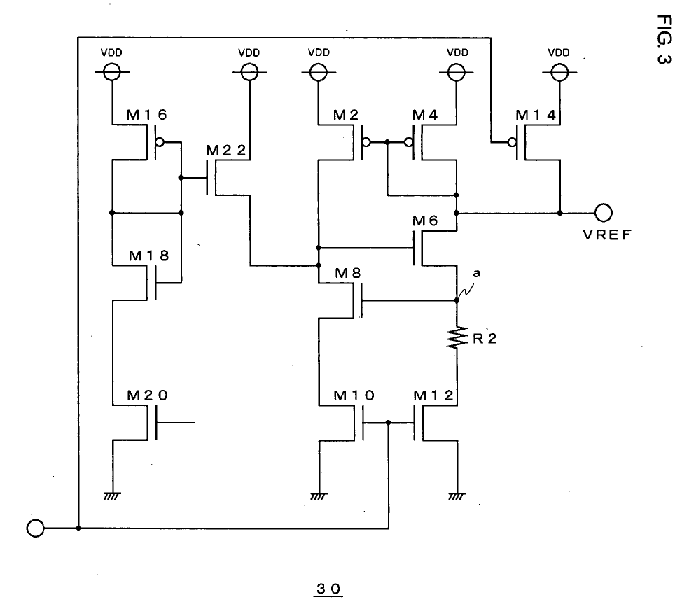

FIG. 3 is a circuit diagram showing the structure of the constant voltage generation circuit 30 according to the first embodiment of the present invention. The constant voltage generation circuit 30 is configured so that values of a voltage “Va” and a current “Ia” at the node “a” in FIG. 3 stay constant even if a power supply voltage fluctuates. A pair of P-channel MOS (Metal-Oxide Semiconductor) field-effect transistors (hereinafter referred to as PMOS transistors), M2 and M4, constitutes a current mirror circuit. Source terminals of a first PMOS transistor M2 and a second PMOS transistor M4 are connected to the power supply voltage VDD. A gate terminal of M2 is connected to a gate terminal of M4. A node at which the gate terminal of M2 is connected to the gate terminal of M4, is connected to a drain terminal of the second PMOS transistor M4, and the same voltage is applied to the gate terminals of the first PMOS transistor M2 and the second PMOS transistor M4. If the driving current capacity is equivalent for the first PMOS transistor M2 and the second PMOS transistor M4, an equal current flows in both M2 and M4.

The drain terminal of the second PMOS transistor M4, is connected to a drain terminal of a first N-channel MOS field-effect transistor (hereinafter referred to as NMOS transistor) M6. A node at which the drain terminal of the second PMOS transistor M4 is connected to the drain terminal of the first NMOS transistor M6, is connected to the output terminal of the constant voltage generation circuit 30 so that an output voltage VREF can be supplied to outside of the constant voltage generation circuit 30. A gate terminal of the first NMOS transistor M6 is connected to a drain terminal of the first PMOS transistor M2.

The drain terminal of the first PMOS transistor M2 is connected to a drain terminal of a second NMOS transistor M8. A gate terminal of the second NMOS transistor M8 is connected to a source terminal of the first NMOS transistor M6. The source terminal of the first NMOS transistor M6 is connected to a resistor R2 in series, and a source voltage of the first NMOS transistor M6 is stepped down due to the resistor R2.

The first NMOS transistor M6 and the second NMOS transistor M8 form a loop so that the source voltage of the first NMOS transistor M6 and a current flowing in the resistor R2 are kept constant. That is to say, a gate voltage and a drain voltage of the second NMOS transistor M8 fluctuates in accordance with fluctuations of the source voltage of the first NMOS transistor M6, and the gate voltage is adjusted so as to keep the source voltage of the first NMOS transistor M6 constant.

The other terminal of the resistor R2 and the source terminal of the second NMOS transistor M8 are connected to ground via a pair of NMOS transistors, a third NMOS transistor M10 and a fourth NMOS transistor M12. A third PMOS transistor M14 is provided with a source terminal of the third PMOS transistor M14 connected to the power supply voltage and with a drain terminal of the third PMOS transistor M14 connected to a node of the output voltage VREF. A mode signal is input to a gate of the third PMOS transistor M14 and to gates of a pair of the third and fourth NMOS transistors, M10 and M12.

The mode signal decides an operation mode of the constant voltage generation circuit 30. When a voltage signal whose level is higher than a threshold level is input, a first mode is set up with a pair of the third and fourth NMOS transistors, M10 and M12, turned on, and with the third PMOS transistor M14 turned off. In this mode, the drain voltage of the second PMOS transistor M4 is output to outside of the constant voltage generation circuit 30. On the other hand, when a voltage signal whose level is lower than the threshold level is input, a second mode is set up with a pair of the third and fourth NMOS transistors, M10 and M12, turned off, and with the third PMOS transistor M14 turned on. In this mode, the drain voltage of the third PMOS transistor M14 is output to outside of the constant voltage generation circuit 30. In the first mode, since a current pathway is formed in the first NMOS transistor M6, an output current to outside of the constant voltage generation circuit 30 can be reduced.

A fourth PMOS transistor M16 and a fifth NMOS transistor M18, which constitute a push-pull circuit, are also provided. A source terminal of the fourth PMOS transistor M16 is connected to the power supply voltage VDD, and a source terminal of the fifth NMOS transistor M18 is connected to ground via a sixth NMOS transistor M20 employed as a switch.

Additionally, a seventh NMOS transistor M22 is provided with a drain terminal of the seventh NMOS transistor M22 connected to the power supply voltage VDD and a source terminal of the seventh NMOS transistor M22 connected to the drain terminal of the second NMOS transistor M8, so as to fit the confines of the aforementioned loop. A gate terminal of the seventh NMOS transistor M22 is connected to a node where the fourth PMOS transistor M16 and the fifth NMOS transistor M18, which constitute the push-pull circuit, are connected with each other.

In this circuit configuration, applying a voltage intermittently in the aforementioned loop can prevent the source voltage of the first NMOS transistor M6 and an operating point of the current flowing in the resistor R2 from falling to neighborhood of 0V.

Thus, the constant voltage generation circuit 30 can maintain the source voltage of the first NMOS transistor M6 and the current flowing in the resistor R2. Therefore, the output voltage VREF varies in accordance with variations of the power supply voltage VDD, i.e., a difference between the power supply voltage VDD and the output voltage VREF is kept constant even if the power supply voltage VDD fluctuates.

According to the embodiment as described hereinbefore, by utilizing a voltage generated by the same voltage source to control a current flowing in a delay circuit and a current flowing in an operational amplifier, adjustment of an operation speed can be achieved in a circuit which carries out a function and includes the delay circuit and the operational amplifier, without a design change in the delay circuit and the operational amplifier. In case of increasing the operation speed of the operational amplifier, for instance, by stepping up a voltage from the voltage source, a current flowing in the delay circuit and the operational amplifier can be increased and a delay period in the delay circuit can be shorter. At the same time, since a ratio of a master clock to delayed clock is maintained for any clock rates in the master clock, it is not necessary to make a design change in the delay circuit.

Additionally, when the output voltage from the constant voltage generation circuit according to FIG. 3 is employed as a bias voltage for a delay circuit, current flowing in invertors that constitute the delay circuit can be kept constant since the bias voltage varies in accordance with a power supply voltage VDD. Hence, the delay circuit can restrain the variations in delay values due to fluctuation of power supply voltage, environmental change such as temperature change, piece-to-piece variations of devices, etc. Consequently, a delayed clock with high accuracy can be generated to supply a circuit including an operational amplifier, which makes it possible to improve the accuracy of the entire electronic circuit.

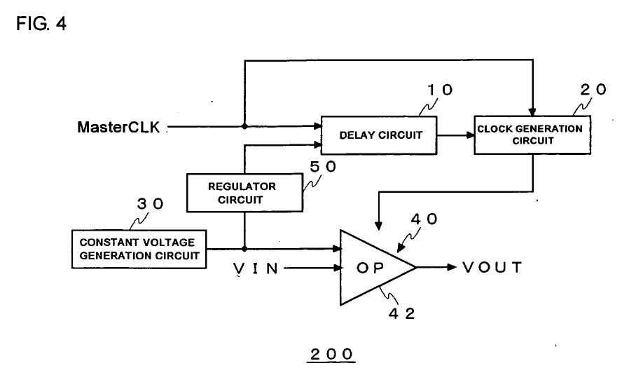

The circuit configuration in which the output voltage of the constant voltage generation circuit 30 is directly input to the delay circuit 10 is described in the above-mentioned embodiment. Herein, a regulator circuit 50 may be disposed on the path P2 between the constant voltage generation circuit 30 and the delay circuit 10. FIG. 4 is a block diagram showing a structure of an electronic circuit 200 according to a modification of the first embodiment of the present invention. The electronic circuit 200 has a circuit configuration with the regulator circuit 50 added to the electronic circuit 100 in FIG. 1. The constant voltage generation circuit 30 generates an output voltage to the regulator circuit 50, and the regulator circuit 50 regulates the voltage to a desired value and outputs the regulated voltage to the delay circuit 10. For example, when the output voltage from the constant voltage generation circuit 30 is too high to input directly to the delay circuit 10, a step-down transformer may be disposed as the regulator circuit 50 on the path P2 between the constant voltage generation circuit 30 and the delay circuit 10. According to this aspect, a voltage source can be shared by the operational amplifier and the delay circuit without making a design change in the delay circuit and the operational amplifier.

Although the present invention has been fully described by the above-mentioned embodiment, it is to be noted that various changes and modification in the combinations of constituents and handling process will be apparent to those skilled in the art. Therefore, unless otherwise such changes and modifications depart from the scope of the present invention, they should be construed as being included therein.

What is claimed is:

1. An electronic circuit comprising:
a voltage generation circuit which generates a bias voltage;
an operational amplifier which operates with a constant voltage and receives said bias voltage from said voltage generation circuit; and
a delay circuit which operates with said constant voltage and receives said bias voltage from said voltage generation circuit so as to reduce fluctuations of current flowing in said delay circuit by said bias voltage.

2. The electronic circuit according to claim 1, further comprising a regulator circuit which is connected to each of said voltage generation circuit and said delay circuit, and regulates said bias voltage from said voltage generation circuit.

3. The electronic circuit according to claim 2, wherein said voltage generation circuit fluctuates said bias voltage supplied to said delay circuit in accordance with fluctuations of said constant voltage.

4. The electronic circuit according to claim 1, wherein said voltage generation circuit fluctuates said bias voltage supplied to said delay circuit in accordance with fluctuations of said constant voltage.

5. An electronic circuit comprising:
a voltage generation circuit which generates an bias voltage;
an operational amplifier which operates with a constant voltage and receives said bias voltage from said voltage generation circuit;
a delay circuit which operates with said constant voltage and receives said bias voltage from said voltage generation circuit so as to reduce fluctuations of current flowing in said delay circuit by said bias voltage; and
a clock generation circuit which generates a clock signal to supply said operational amplifier and an additional circuit added to said operational amplifier;
wherein said clock signal is generated based on a signal before being delayed by said delay circuit and on a signal after being delayed by said delay circuit.

6. The electronic circuit according to claim 5, further comprising a regulator circuit which is connected to each of said voltage generation circuit and said delay circuit, and regulates said bias voltage from said voltage generation circuit.

7. The electronic circuit according to claim 6, wherein said voltage generation circuit fluctuates said bias voltage supplied to said delay circuit in accordance with fluctuations of said constant voltage.

8. The electronic circuit according to claim 5, wherein said voltage generation circuit fluctuates said bias voltage supplied to said delay circuit in accordance with fluctuations of said constant voltage.

9. A delay circuit operating with a constant voltage and receives a bias voltage so as to reduce fluctuations of current flowing in said delay circuit, wherein said bias voltage is supplied by a voltage source provided to supply said bias voltage to an operational amplifier disposed outside of said delay circuit.
